(19) United States
(12) Patent Application Publication
(10) Pub. No.: US 2025/0287764 A1
(43) Pub. Date: Sep. 11, 2025

(54) DISPLAY DEVICE AND REPAIR METHOD FOR DISPLAY DEVICE

(71) Applicant: Japan Display Inc., Tokyo (JP)

(72) Inventor: Kazuyuki YAMADA, Tokyo (JP)

(21) Appl. No.: 19/047,980

(22) Filed: Feb. 7, 2025

(30) Foreign Application Priority Data
Mar. 6, 2024 (JP) 2024-033572

(51) Int. Cl. H10H 29/85; G09G 3/00; H01L 25/075

(52) U.S. Cl. CPC H10H 29/857; G09G 3/006; H01L 25/0753; G09G 2330/12

(57) ABSTRACT

A display device includes a first LED chip arranged in a pixel, a first mounting pad arranged in the pixel and connected to the first LED chip, a second mounting pad arranged in the pixel, overlapping the first mounting pad in a plan view and electrically connected to the second mounting pad, and an insulating layer between the first mounting pad and the second mounting pad.

### CROSS REFERENCE TO RELATED APPLICATIONS

This application claims the benefit of priority to Japanese Patent Application No. 2024-033572, filed on Mar. 6, 2024, the entire contents of which are incorporated herein by reference.

### FIELD

One embodiment of the present invention relates to a display device and a repair method for a display device. In particular, the present invention relates to a display device with an LED (Light Emitting Diode) chip and a repair method for the display device.

### BACKGROUND

Recently, an LED display in which a minute LED chip is mounted on each pixel is being developed as a next-generation display device. Normally, an LED display has a structure in which a plurality of LED chips is mounted on a circuit substrate constituting a pixel array. The circuit substrate has a drive circuit for causing an LED to emit light at a position corresponding to each pixel. These drive circuits are electrically connected to each LED chip, respectively.

There are various methods for mounting a plurality of LED chips on a circuit substrate. For example, there is the well-known method of removing only the support substrate after bonding the LED chips on the support substrate to the circuit substrate. For example, Japanese laid-open patent publication No. 2023-005830 describes a technique for selectively irradiating laser light to LED chips at a high throughput by using a light-shielding mask.

In a display device with mounted LED chips, there is a need to improve the yield rate when mounting the LED chips from the support substrate to the circuit substrate. For example, a connection failure between the LED chip and the circuit substrate will reduce the yield. Such a connection failure is undesirable since it causes defects in the pixel.

### SUMMARY

A display device in an embodiment according to the present invention includes a first LED chip arranged in a pixel, a first mounting pad arranged in the pixel and connected to the first LED chip, a second mounting pad overlapping and electrically connected to the first mounting pad in a plan view, and an insulating layer between the first mounting pad and the second mounting pad.

A repair method for a display device in an embodiment according to the present invention, the method includes irradiating a first laser light to a first LED chip determined to be defective in a pixel and removing the first LED chip, irradiating a second laser light to a first mounting pad connected to the first LED chip in the pixel and removing the first mounting pad, irradiating a third laser light to an insulating layer overlapping the first mounting pad and removing the insulating layer, and exposing a second mounting pad overlapping the first mounting pad in a plan view, and mounting a second LED chip on the second mounting pad.

### BRIEF DESCRIPTION OF DRAWINGS

FIG. 1 is a plan view showing a schematic configuration of a display device according to an embodiment of the present invention.

FIG. 2 is a block diagram showing a circuit configuration of the display device according to an embodiment of the present invention.

FIG. 3 is an example of a circuit diagram showing a configuration of a pixel circuit of the display device according to an embodiment of the present invention.

FIG. 4 is a plan view showing a schematic configuration of a pixel in a display device according to an embodiment of the present invention.

FIG. 5 is a cross-sectional view showing a schematic configuration of a pixel in a display device according to an embodiment of the present invention.

FIG. 6 is a plan view showing a schematic configuration of a pixel in a display device according to an embodiment of the present invention.

FIG. 7 is a cross-sectional view showing a schematic configuration of a pixel in a display device according to an embodiment of the present invention.

FIG. 8 is a flowchart showing a repair method for a display device according to an embodiment of the present invention.

FIG. 9 is a cross-sectional view showing a repair method for a display device according to an embodiment of the present invention.

FIG. 10 is a cross-sectional view showing a repair method for a display device according to an embodiment of the present invention.

FIG. 11 is a cross-sectional view showing a repair method for a display device according to an embodiment of the present invention.

FIG. 12 is a cross-sectional view showing a repair method for a display device according to an embodiment of the present invention.

FIG. 13 is a cross-sectional view showing a repair method for a display device according to an embodiment of the present invention.

FIG. 14 is a plan view showing a schematic configuration of a repaired pixel in a display device according to an embodiment of the present invention.

### DESCRIPTION OF EMBODIMENTS

Embodiments of the present invention will be described below with reference to the drawings and the like. However, the present invention can be implemented in various modes without departing from the gist thereof. The present invention is not to be construed as being limited to the description of the following exemplary embodiments. For the sake of clarity of description, the drawings may be schematically represented with respect to widths, thicknesses, shapes, and the like of the respective portions in comparison with actual modes. However, the drawings are merely examples and do not limit the interpretation of the present invention.

In describing the present embodiment, a direction from a substrate to an LED chip is “above” and the opposite direction is “below”. However, the expression “above” or “below” merely describes the upper limit relationship of each element. For example, the expression that an LED chip is arranged above a substrate also includes the presence of other members between the substrate and the LED chip. Furthermore, the expression “above” or “below” includes not only the case where chips overlap but also the case where they do not overlap in a plan view.

In the description of the embodiment of the present invention, elements having the same functions as those of the elements already described are denoted by the same symbols or the same symbols with symbols such as letters of the alphabet, and the description thereof may be omitted. For example, in the case where an element needs to be described separately for each color of RGB, it may be distinguished by the symbols R, G, or B after the symbols indicating the element. On the other hand, in the case where the elements need not be described separately for each color of RGB, only a symbol indicating the elements will be used.

### First Embodiment

A display device 10 according to one embodiment of the present invention will be described

### [Configuration of Display Device]

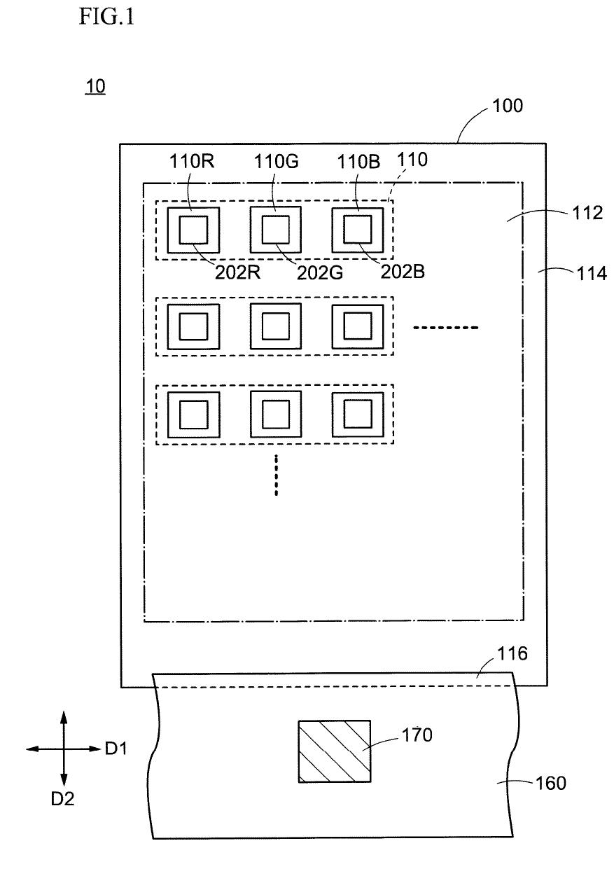

FIG. 1 is a plan view showing a schematic configuration of a display device according to an embodiment of the present invention. The display device 10 has a circuit substrate 100, a flexible printed circuit substrate 160 (FPC 160), and an IC chip 170 as shown in FIG. 1. The display device 10 has a display area 112, a peripheral area 114, and a terminal area 116.

The display area 112 is an area in which a plurality of pixels 110 including an LED chip 202 is arranged in a row direction (D1 direction) and a column direction (D2 direction). Specifically, in the present embodiment, a pixel 110R including a red LED element 202R, a pixel 110G including a green LED element 202G, and a pixel 110B including a blue LED element 202B are arranged in the area. FIG. 1 shows an example in which the pixel 110R, pixel 110G, and pixel 110B are sub-pixels, and they constitute a single pixel 110. The display area 112 functions as an area for displaying an image corresponding to a video signal.

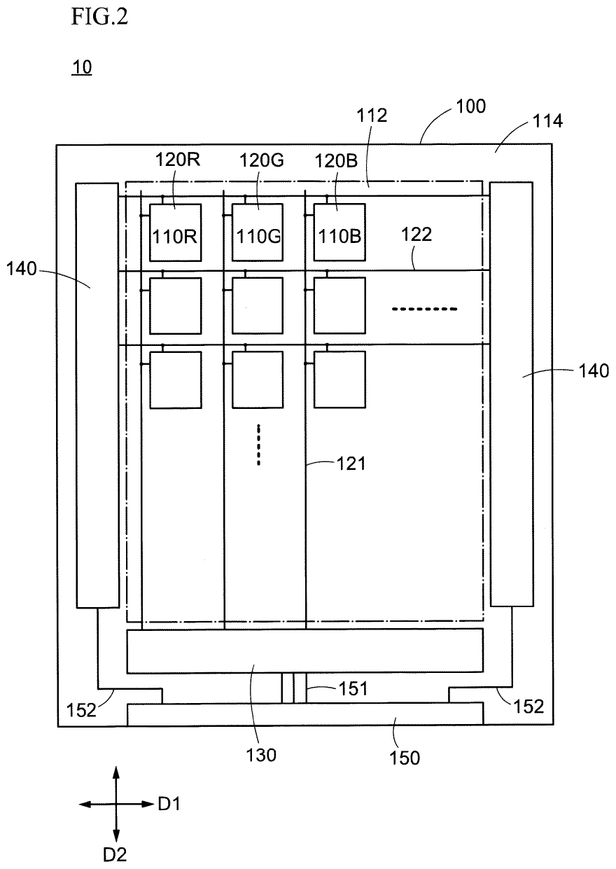

The peripheral area 114 is an area around the display area 112. The peripheral area 114 is an area provided with driver circuits (a data driver circuit 130 and a gate driver circuit 140 shown in FIG. 2) for controlling pixel circuits (pixel circuits 120 shown in FIG. 2) provided in each pixel 110.

The terminal area 116 is an area in which a plurality of wirings connected to the aforementioned driver circuits is aggregated. The flexible printed circuit substrate 160 is electrically connected to a plurality of wirings in the terminal area 116. A video signal (data signal) or control signal output from an external device (not shown) is input to the IC chip 170 via the wiring (not shown) provided in the flexible printed circuit substrate 160. The IC chip 170 performs various signal processing on the video signal and generates a control signal required for display control. The video signal and control signal output from the IC chip 170 are input to the display device 10 via the flexible printed circuit substrate 160.

### [Circuit Configuration of Display Device 10]

FIG. 2 is a block diagram showing a circuit configuration of the display device 10 according to one embodiment of the present invention. As shown in FIG. 2, the display area 112 is provided with the pixel circuit 120 corresponding to each pixel 110. In the present embodiment, the pixel circuit 120R, the pixel circuit 120G, and the pixel circuit 120B are provided corresponding to the pixel 110R, the pixel 110G, and the pixel 110B, respectively. That is, a plurality of pixel circuits 120 is arranged in the row direction (D1 direction) and the column direction (D2 direction) in the display area 112.

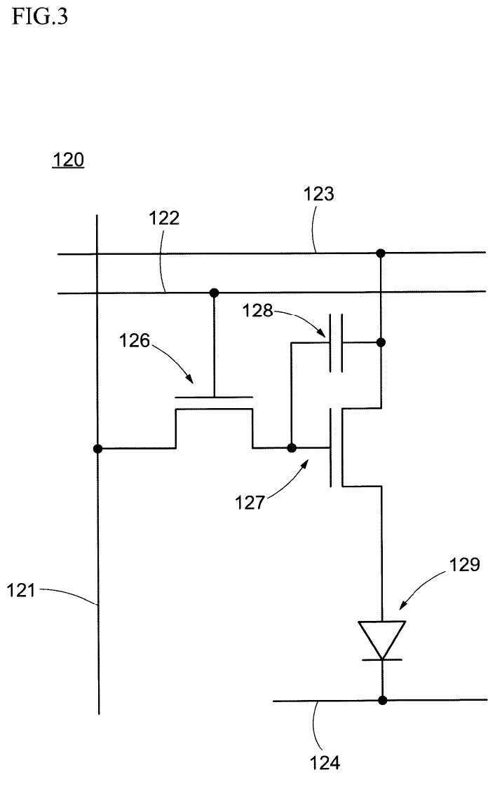

FIG. 3 is a circuit diagram showing a configuration of the pixel circuit 120 of the display device 10 according to one embodiment of the present invention. The pixel circuit 120 is arranged in an area surrounded by a data line 121, a gate line 122, an anode power line 123, and a cathode power line 124. The pixel circuit 120 of the present embodiment includes a select transistor 126, a drive transistor 127, a storage capacity 128, and an LED 129. The LED 129 corresponds to the LED chip 202 shown in FIG. 1. In the pixel circuit 120, circuit elements other than the LED 129 correspond to a drive circuit 102 provided in the circuit substrate 100. That is, the pixel circuit 120 is completed with the LED chip 202 mounted on the circuit substrate 100.

As shown in FIG. 3, a source electrode, gate electrode, and drain electrode of the select transistor 126 are connected to the data line 121, the gate line 122, and a gate electrode of the drive transistor 127, respectively. The source electrode, gate electrode, and drain electrode of the drive transistor 127 are connected to the anode power line 123, a drain electrode of the select transistor 126, and the LED 129, respectively. The storage capacity 128 is connected between the gate electrode and the drain electrode of the drive transistor 127. That is, the storage capacity 128 is connected to the drain electrode of the select transistor 126. The anode and cathode of the LED 129 are connected to the drain electrode of the drive transistor 127 and the cathode power line 124, respectively.

A gradation signal for determining an emission intensity of the LED 129 is supplied to the data line 121. A gate signal for selecting the select transistor 126 that writes the gradation signal is supplied to the gate line 122. When the select transistor 126 is turned on, the gradation signal is stored in the storage capacity 128. Thereafter, when the drive transistor 127 is turned on, a drive current corresponding to the gradation signal flows through the drive transistor 127. When the drive current output from the drive transistor 127 is input to the LED 129, the LED 129 emits light with a light emission intensity corresponding to the gradation signal.

Referring to FIG. 2 again, a data driver circuit 130 is arranged at a position adjacent to the display area 112 in the column direction (D2 direction). A gate driver circuit 140 is arranged at a position adjacent to the display area 112 in the row direction (D1 direction). In the present embodiment, although two gate driver circuits 140 are provided on both sides of the display area 112, only one of them may be provided.

Both the data driver circuit 130 and the gate driver circuit 140 are arranged in the peripheral area 114. However, the area where the data driver circuit 130 is arranged is not limited to the peripheral area 114. For example, the data driver circuit 130 may be arranged on the flexible printed circuit substrate 160.

The data line 121 shown in FIG. 3 extends from the data driver circuit 130 in the D2 direction and is connected to the source electrode of the select transistor 126 in each pixel circuit 120. The gate line 122 extends from the gate driver circuit 140 in the D1 direction and is connected to the gate electrode of the select transistor 126 in each pixel circuit 120.

A terminal portion 150 is arranged in the terminal area 116. The terminal portion 150 is connected to the data driver circuit 130 via a connecting wiring 151. Similarly, the terminal portion 150 is connected to the gate driver circuit 140 via a connecting wiring 152. In addition, the terminal portion 150 is connected to the flexible printed circuit substrate 160.

### [Configuration of Pixel 110]

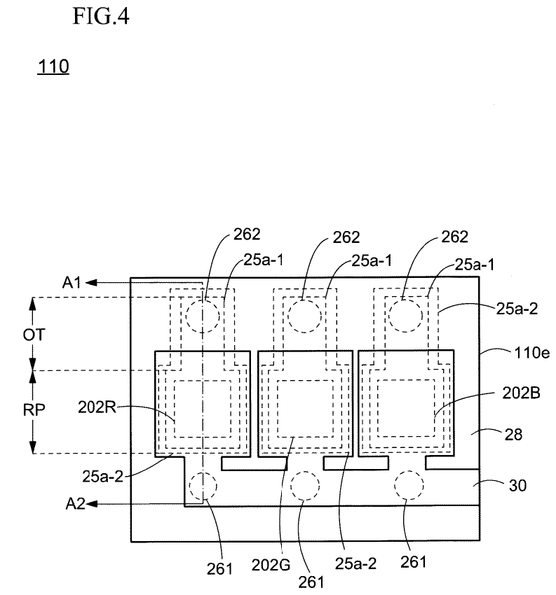

FIG. 4 is a plan view showing a pixel of a display device according to an embodiment of the present invention. An LED chip 202, a first mounting pad 25a-1, a second mounting pad 25a-2, and a conductive layer 30 are arranged in the pixel 110. As shown in FIG. 4, the first mounting pad 25a-1 and the second mounting pad 25a-2 are arranged corresponding to each of the red LED chip 202R, the green LED chip 202G, and the blue LED chip 202B.

The mounting pad in the present embodiment is an area formed by a metal film for mounting the LED chip on the substrate, and is an electrode. The shape of the mounting pad in a plan view is optional, and may be designed as needed to adapt to the electrode shape and electrode arrangement of the LED chip.

The LED chip 202 overlaps the first mounting pad 25a-1, the second mounting pad 25a-2, and the conductive layer 30 in a plan view. In a plan view, the area occupied by the LED chip 202 is smaller than the area of the first mounting pad 25a-1, the second mounting pad 25a-2, and the conductive layer 30. The larger area of the first mounting pad 25a-1, the second mounting pad 25a-2, and the conductive layer 30 relative to the area of the LED chip 202 can provide a margin of alignment accuracy when mounting the LED chip 202 on the pad.

The first mounting pad 25a-1 may have a region that overlaps the LED chip 202 and the second mounting pad 25a-2 and a region that does not overlap the LED chip 202.

A new LED chip 402 (not shown) may be mounted in the region where the LED chip 202 is mounted in place of the currently mounted LED chip 202, as described below in detail. When mounting the new LED chip 402, the LED chip 202 is removed and the first mounting pad 25a-1 is removed to further expose the top surface of the second mounting pad 25a-2.

A connection portion is provided to electrically connect the first mounting pad 25a-1 and the second mounting pad 25a-2 in the region where the LED chip 202 does not overlap the first mounting pad 25a-1 and the second mounting pad 25a-2. As shown in FIG. 4, the first mounting pad 25a-1 is connected to the second mounting pad 25a-2 through a contact hole 262 arranged in the region where the first mounting pad 25a-1 and the second mounting pad 25a-2 overlap. By connecting the first mounting pad 25a-1 and the second mounting pad 25a-2, the same potential can be provided to the first mounting pad 25a-1 and the second mounting pad 25a-2.

The first mounting pad 25a-1 may be formed to surround the LED chip 202. The first mounting pad 25a-1 has a portion surrounding the LED chip 202 and a portion extending from the portion surrounding the LED chip 202 toward an outer edge 110e of the pixel 110, as shown in FIG. 4. Here, the portion surrounding the LED chip 202 corresponds to the region overlapping the LED chip 202 and the second mounting pad 25a-2 of the first mounting pad 25a-1 as described above, and the portion extending from the portion surrounding the LED chip 202 to the outer edge 110e of the pixel 110 corresponds to the region of the first mounting pad 25a-1 that does not overlap the LED chip 202.

The area of the first mounting pad 25a-1 may be smaller than the area of the second mounting pad 25a-2. When a plurality of red LED chips 202R, green LED chips 202G, and blue LED chips 202B are provided in the pixel 110, as shown in FIG. 4, for example, since area of the first mounting pad 25a-1 is small, the distance between the first mounting pads 25a-1 connecting to each of the plurality of LED chips 202 becomes longer. The longer distance makes it easier to remove the first mounting pad 25a-1 connecting to one of the plurality of LED chips 202. However, depending on the arrangement of the plurality of LED chips 202 in the pixel 110, the area of the first mounting pad 25a-1 may be larger than the area of the second mounting pad 25a-2.

The second mounting pad 25a-2 may be formed to surround the LED chip 202 and the first mounting pad 25a-1. The second mounting pad 25a-2 may have a portion surrounding the LED chip 202 and a portion extending from the portion surrounding the LED chip 202 to the outer edge 110e of the pixel 110, as shown in FIG. 4. The portion surrounding the LED chip 202 corresponds to a repair region RP, the portion surrounding the LED chip 202 and the portion extending from the portion surrounding the LED chip 202 to the outer edge 110e of the pixel 110 corresponds to a region OT.

The repair region RP is a region where a new LED chip 302 is mounted in place of the currently mounted LED chip 202 when the LED chip 202 is determined to be defective. The region OT is a region where a portion to be connected to the first mounting pad 25a-1 is arranged.

The first mounting pad 25a-1 and the second mounting pad 25a-2 are arranged to be separated from adjacent first mounting pads 25a-1 and second mounting pads 25a-2. When a plurality of LED chips 202 are arranged in the pixel 110, the first mounting pad 25a-1 and the second mounting pad 25a-2, which connect to each of the plurality of

LED chips 202, are arranged at a distance. As shown in FIG. 4, the first mounting pad 25a-1 and the second mounting pad 25a-2, which overlap and are electrically connected with the red LED chip 202R, are arranged to be separated from the first mounting pad 25a-1 and the second mounting pad 25a-2, which overlap and are electrically connected with the adjacent green LED chip 202G.

The conductive layer 30 may be electrically connected to the LED chip 202. The conductive layer 30 is arranged to overlap the LED chip 202, the first mounting pad 25a-1, and the second mounting pad 25a-2. The conductive layer 30 may be formed to surround the LED chip 202. As shown in FIG. 4, the conductive layer 30 may have a portion surrounding the LED chip 202 and a portion extending from the portion surrounding the LED chip 202 toward the outer edge 110e of the pixel 110. The portion of the conductive layer 30 extending toward the outer edge 110e of the pixel 110 connects with the conductive layer 30 which electrically connects to the other LED chips 202 when multiple LED chips 202 are provided in the pixel 110. For example, as shown in FIG. 4, the conductive layer 30 that overlaps and is electrically connected with the red LED chip 202R is connected to the conductive layer 30 that overlaps and is electrically connected with the green LED chip 202G at a portion extending toward the outer edge 110e of the pixel 110. As such, it is possible to provide the same potential to those conductive layers 30 by connecting the conductive layers 30 electrically connected to the plurality of LED chips 202 in the same pixel 110 to each other.

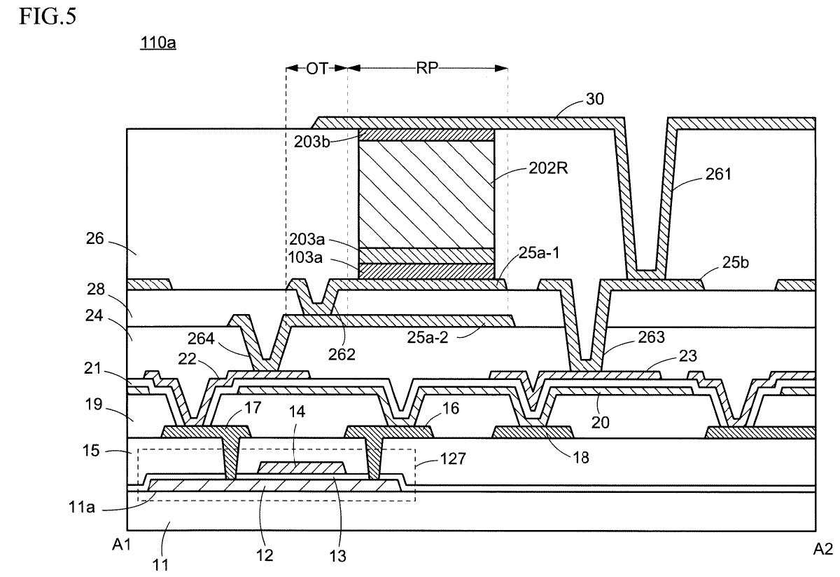

FIG. 5 is a cross-sectional view showing a configuration of the pixel in a display device according to one embodiment of the present invention. Specifically, FIG. 5 is a cross-sectional view along the A1-A2 line in FIG. 4. In FIG. 5, the same reference number is attached to the same configuration of the pixel 110 shown in FIG. 4, and redundant explanations are omitted.

The pixel 110 has the drive transistor 127 provided on an insulating substrate 11. A glass substrate or a transparent substrate with an insulating layer on a resin substrate may be used as the insulating layer 11.

The drive transistor 127 has a semiconductor layer 12, a gate insulating layer 13, and a gate electrode 14. A source electrode 16 and a drain electrode 17 are connected to the semiconductor layer 12 via an insulating layer 15. Although not shown, the gate electrode 14 is connected to a drain electrode of the select transistor 126 shown in FIG. 3.

A wiring 18 is provided in the same layer as the source electrode 16 and the drain electrode 17. The wiring 18 functions as the anode power line 123 shown in FIG. 3. Therefore, the source electrode 16 and the wiring 18 are electrically connected by a connecting wiring 20 provided on a planarization layer 19. The planarization layer 19 is a transparent resin layer using a resinous material such as polyimide or acrylic. The connecting wiring 20 is a transparent conductive layer using a metal oxide material such as ITO. However, the present invention is not limited to this example, and other metal materials may be used as the connecting wiring 20.

An insulating layer 21 composed of silicon nitride or the like is provided on the connecting wiring 20. A conductive layer 22 and a conductive layer 23 are provided on the insulating layer 21. In the present embodiment, the conductive layer 22 and the conductive layer 23 are electrodes consisting of a light-shielding metallic material. The conductive layer 22 is connected to the drain electrode 17 through contact hole(s) (opening(s)) in the planarization layer 19 and the insulating layer 21.

A planarization layer 24 is provided on the conductive layer 22 and the conductive layer 23. The planarization layer 24 is a transparent resin layer composed of polyimide, acrylic, or other resin material.

The second mounting pad 25a-2 is formed on the planarization layer 24. The second mounting pad 25a-2 is connected to the conductive layer 22 through a contact hole 264 in the planarization layer 24.

An insulating layer 28 is provided on the second mounting pad 25a-2. The thickness of the insulating layer 28 is greater than or equal to 1 μm and less than or equal to 2 μm. The insulating layer 28 is an organic insulating layer composed of a photosensitive resin material or the like. The organic insulating layer having a thickness greater than 1 μm and less than 2 μm used for the insulating layer 28 provides ease of removal by laser or other means.

The first mounting pad 25a-1 and a mounting pad 25b are provided on the insulating layer 28. The first mounting pad 25a-1 is arranged to overlap the second mounting pad 25a-2 in a cross-sectional view. The insulating layer 28 is arranged between the first mounting pad 25a-1 and the second mounting pad 25a-2.

The first mounting pad 25a-1 is connected to the second mounting pad 25a-2 through the contact hole 262 provided in the insulating layer 28. The first mounting pad 25a-1 connecting with the second mounting pad 25a-2 can provide the same potential as described above. The second mounting pad 25a-2 is at the same potential as the first mounting pad 25a-1 and is arranged in the same pixel 110 so that the second mounting pad 25a-2 can function as a spare mounting pad for the first mounting pad 25a-1. Furthermore, the second mounting pad 25a-2 is arranged to overlap the first mounting pad 25a-1, and the first mounting pad 25a-1 is removed so that the second mounting pad 25a-2 can be used as a spare mounting pad for the first mounting pad 25a-1.

The mounting pad 25b is connected to the conductive layer 23 through the contact holes 263 in the planarization layer 24 and the insulating layer 28. In FIG. 5, although the connection between the mounting pad 25b and the conductive layer 23 is through the contact hole 263 only, they may be electrically connected through a plurality of contact holes, as in the connection between the first mounting pad 25a-1 and the conductive layer 22. The first mounting pad 25a-1, the second mounting pad 25a-2, and the mounting pad 25b are composed of metallic materials such as aluminum, titanium, molybdenum, tantalum, tungsten, etc.

The LED chip 202 is provided on the first mounting pad 25a-1. The LED chip 202 is arranged to overlap the first mounting pad 25a-1, the second mounting pad 25a-2, and the insulation layer 28. The LED chip 202 is arranged so as not to overlap the contact hole 262 and the contact hole 264. The contact hole 262 may be arranged between the LED chip 202 and the contact hole 264. The contact hole 262 is arranged between the LED chip 202 and the contact hole 264 without the LED chip 202 overlapping the contact hole 264 and the contact hole 262 so that when installing a new LED chip 402 (not shown) in place of the LED chip 202, damage to the contact holes 264 due to removal of the LED chip 202 can be prevented.

The LED chip 202 corresponds to the LED 129 in the circuit diagram shown in FIG. 3. An anode 303a of the LED chip 202 is connected to the conductive layer 22 connected to the drain electrode 17 of the drive transistor 127. A cathode 203b of the LED chip 202 is connected to the conductive layer 23. The conductive layer 23 is electrically connected to the cathode power line 124 shown in FIG. 3. The arrangement of the anode 203a and cathode 203b shown in FIG. 5 is an example, and the arrangement of the anode 203a and cathode 203b may be reversed.

A first connecting electrode 103a is provided between the first mounting pad 25a-1 and the LED chip 202. In the present embodiment, an electrode composed of tin (Sn) is arranged as the first connecting electrode 103a.

The first connecting electrode 103a is bonded to the anode 203a of the LED chip 202. The anode 203a is provided on one of the surfaces of the LED chip 202. On the other hand, the cathode 203b is electrically connected to the conductive layer 30 on the other surface of the LED chip 202. The conductive layer 30 functions as the connecting electrode of the LED chip 202 and is electrically connected to the conductive layer 23. In the present embodiment, the anode 203a and the cathode 203b may be electrodes composed of gold (Au). The first connecting electrode 103a and the anode 203a of the LED chip 202 may be joined to each other by a heat treatment with laser light irradiation. As the laser light, a laser light that is absorbed by the first connecting electrode 103a or the anode 203a may be selected.

A planarization layer 26 is provided over the first mounting pad 25a-1 and the mounting pad 25b. The planarization layer 26 covers the entire side surface of the LED chip 202. The conductive layer 30 is connected to the mounting pad 25b, which is connected to the conductive layer 23 through the contact hole 261 in the planarization layer 26. The planarization layer 26 is a transparent resin layer composed of an insulating resin material such as polyimide, acrylic, or the like.

As described above, the display device 10 according to the present embodiment includes the LED chip 202 arranged in the pixel 110, the first mounting pad 25a-1 arranged in the pixel 110 and connected to the LED chip 202, the second mounting pad 25a-2 arranged in the pixel 110 and overlapping the first mounting pad 25a-1 in a plan view and electrically connected to the second mounting pad 25a-2, and the insulating layer between the first mounting pad 25a-1 and the second mounting pad 25a-2. In the pixel 110 where the first mounting pad 25a-1 is arranged, the second mounting pad 25a-2 is overlapped by and electrically connected to the first mounting pad 25a-1, so that the second mounting pad 25a-2 in the pixel 110 can be provided as a spare mounting pad without providing an additional region for providing the second mounting pad 25a-2. In the display device 10, the small proprietary area per pixel allows more pixels to be provided in the display area 112, thereby providing a high-definition display device.

### <Variation>

In one embodiment of the present invention described above, the LED chip has a structure in which a semiconductor layer and an active layer, not shown, are sandwiched by a pair of the anode 203a and the cathode 203b in the circuit substrate 100, the so-called vertical structure. However, the connection between the LED chip and the connecting electrode on the side of the insulating substrate 11 is not limited to the connection with a vertical structure.

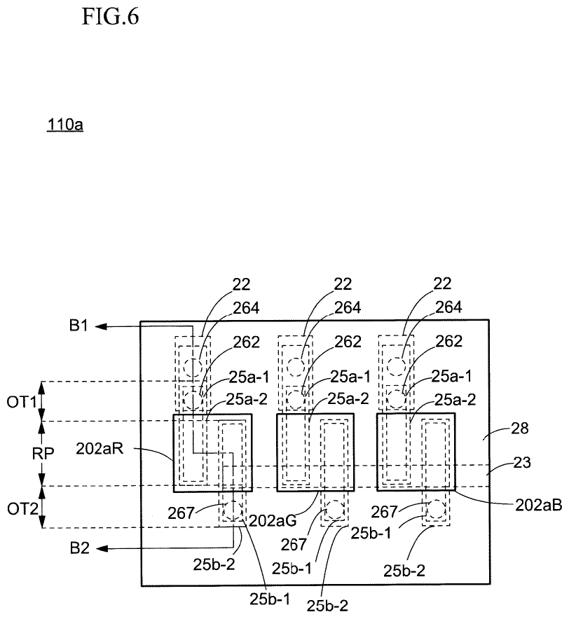

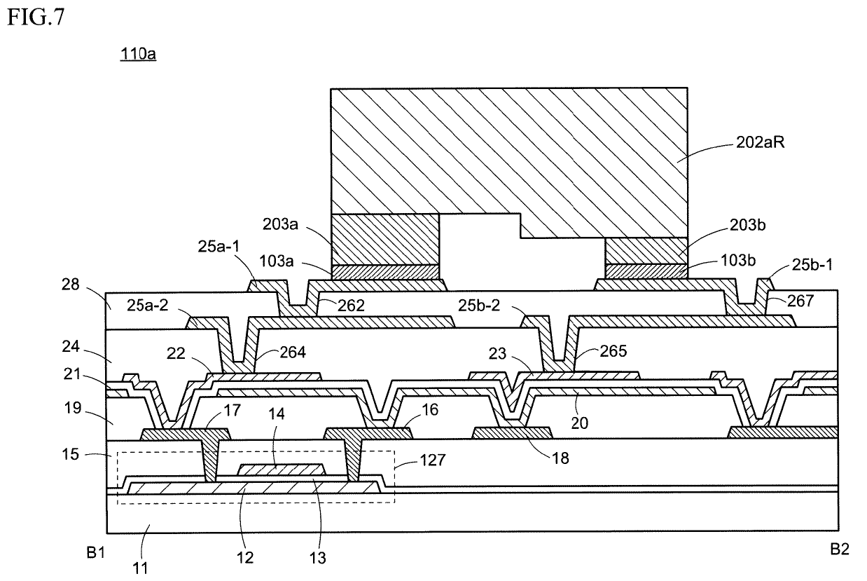

FIG. 6 is a plan view showing the configuration of a pixel 110a of the display device 10 according to a variation of one embodiment of the present invention. FIG. 7 is a cross-sectional view showing the configuration of the pixel 110a of the display device 10 according to a variation of one embodiment of the present invention. As shown in FIG. 7, in the pixel 110a related to the variant example, the LED chip 202aR has an anode 203a electrically connected to the conductive layer 22 and a cathode 203b electrically connected to the conductive layer 23 on one side, and each is electrically connected to the first mounting pad 25a-1 and second mounting pad 25b-1, in a so-called flip chip mounting method. In FIGS. 6 and 7, the same reference numbers are attached to the same configuration of the pixel 110 shown in FIGS. 4 and 5, and redundant explanations are omitted.

The LED chip 202a, the first mounting pad 25a-1, and the second mounting pad 25a-2 are arranged in the pixel 110a. A plurality of LED chips 202 can be provided in the pixel 110a, and a plurality of LED chips 202aR, LED chips 202aG, and LED chips 202aB is arranged in the pixel 101a as shown in FIG. 6.

The LED chip 202a overlaps the first mounting pad 25a-1, the second mounting pad 25a-2, the first mounting pad 25b-1 and the second mounting pad 25b-2 in a plan view.

The first mounting pad 25a-1 overlaps the second mounting pad 25a-2 in a plan view. The first mounting pad 25b-1 overlaps the second mounting pad 25b-2 in a plan view. The first mounting pad 25b-1 may be connected to the second mounting pad 25b-2 in a region not overlapping the LED chip 202a. The first mounting pad 25b-1 may have a portion extending from the portion that overlaps the LED chip 202a to the outer edge 110e of the pixel 110. The portion extending to the outer edge 110e of the pixel 110 of the first mounting pad 25b-1 corresponds to a region which does not overlap the LED chip 202a as shown in FIG.

6. The first mounting pad 25b-1 may be connected through the contact hole 267, which is arranged in a region not overlapping the LED chip 202a. The second mounting pad 25b-2 can be connected to the first mounting pad 25b-1 to provide the same potential as the first mounting pad 25b-1. The second mounting pad 25b-2 is at the same potential as the first mounting pad 25b-1 and is arranged in the same pixel 110 so that the second mounting pad 25a-2 1 can function as a spare mounting pad for the first mounting pad 25b-1. Furthermore, the second mounting pad 25b-2 is arranged to overlap the first mounting pad 25b-1, so that it allows an LED chip to be mounted on the same position where the first mounting pad 25b-1 was mounted by removing the first mounting pad 25b-1.

The pixel 110a has the drive transistor 127 provided on the insulating substrate 11. The structure of the drive transistor 127 shown in FIG. 7 is the same as the drive transistor 127 shown in FIG. 4. The wiring 18 is provided in the same layer as the source electrode 16 and drain electrode 17 of the drive transistor 127. The planarization layer 19 is provided on the source electrode 16, the drain electrode 17 and the wiring 18. The source electrode 16 and the wiring 18 are electrically connected by the connecting wiring 20 provided on the planarization layer 19.

The insulating layer 21 composed of silicon nitride or the like is provided above the connecting wiring 20, and the conductive layer 22 and the conductive layer 23 are provided on the insulating layer 21. The conductive layer 22 is connected to the drain electrode 17 through a contact hole(s) (opening(s)) in the planarization layer 19 and the insulating layer 21.

The conductive layer 22 and the conductive layer 23 are connected to the second mounting pad 25a-2 and the second mounting pad 25b-2 through the contact hole 264 and the contact hole 265 in the planarization layer 24, respectively. The second mounting pad 25b-2 may be configured in the same manner as the second mounting pad 25a-2.

The insulating layer 28 is provided on the second mounting pad 25a-2 and the second mounting pad 25b-2. The first mounting pad 25a- 1 and the first mounting pad 25b-1 are provided on the insulating layer 28. The first mounting pad 25a-1 and the first mounting pad 25b-1 are connected to the second mounting pad 25a-2 and the second mounting pad 25b-2 through the contact hole 262 and the contact hole 267 provided in the insulating layer 28, respectively. The first mounting pad 25b-1 may be configured in the same manner as the first mounting pad 25a-1.

The first mounting pad 25a-1, which is provided on the insulating layer 28 and electrically connects to the anode 203a, and the first mounting pad 25b-1, which is provided on the insulating layer 28 and is electrically connected to the cathode 203b, correspond to a first p-electrode side pad 25 a-1 and a first n-electrode side pad 25b-1 corresponding to the LED chip 202a. The second mounting pad 25a-2, which is provided on the planarization layer 24 and is electrically connected to the anode 203a, and the second mounting pad 25b-2, which is provided on the planarization layer 24 and is electrically connected to the cathode 203b, correspond to a second p-electrode side pad 25a-2 and a second n-electrode side pad 25b-2 corresponding to the LED chip 202a.

The first connecting electrode 103a is provided between the first p-electrode side pad 25a-1 and the anode 203a. The first connecting electrode 103b is provided between the first n-electrode side 25b-1 and cathode 203b. The first connecting electrode 103b may be configured in the same manner as the first mounting pad 25a-1.

### Second Embodiment

The repair method for the display device 10 equipped with the pixel 110 described in the first embodiment will be described. The description may omit descriptions of configurations identical or similar to those described in the first embodiment.

### [Repair Method for Display Device]

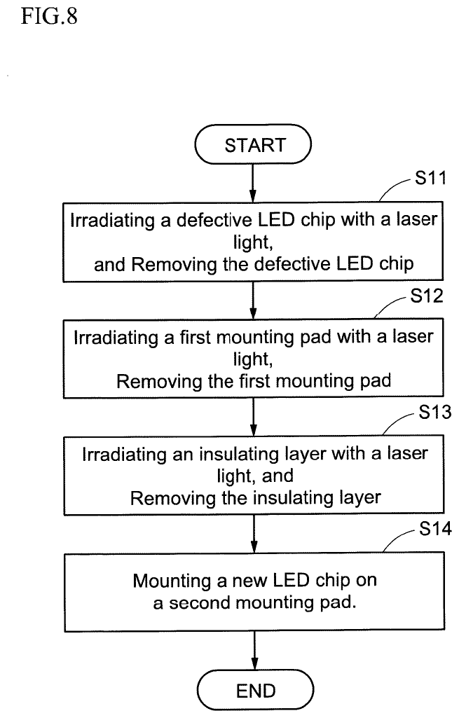

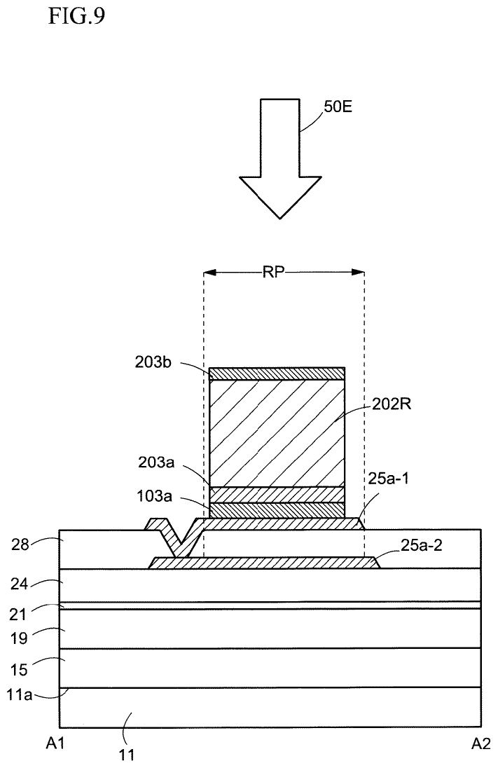

FIG. 8 is a flowchart diagram showing a repair method for a display device according to an embodiment of the present invention. Specifically, FIG. 8 shows the process of removing the LED chip determined to be defective from among a plurality of LED chips 202 formed on the circuit substrate 100 and mounting a new LED chip. FIGS. 9 to 13 are cross-sectional views showing a repair method for a display device according to an embodiment of the present invention. FIGS. 9 to 13 are cross-sectional views showing a repair method for a display device. In FIGS. 9 to 13, the configuration of the pixel 110 shown in FIG. 5 is shown in a simplified form. The process of removing an LED chip determined to be defective from the circuit substrate 100 and mounting a new LED chip on the circuit substrate 100 is described here while referring to FIG. 8.

First, in step S11 of FIG. 8, the red LED chip 202R that is arranged in the pixel 110 and determined to be defective is removed. For example, if the red LED chip 202R shown in FIG. 4 is determined to be defective, the red LED chip 202R arranged in the pixel 110 and determined to be defective is irradiated with a laser light 50E, and the red LED chip 202R is removed from the pixel 110.

The laser light 50E can be selected as a laser light that can be absorbed by the red LED chip 202R. In the present embodiment, for example, ultraviolet light may be used as the laser light 50E. An excimer laser or the like may be used as the light source of the laser light 50E.

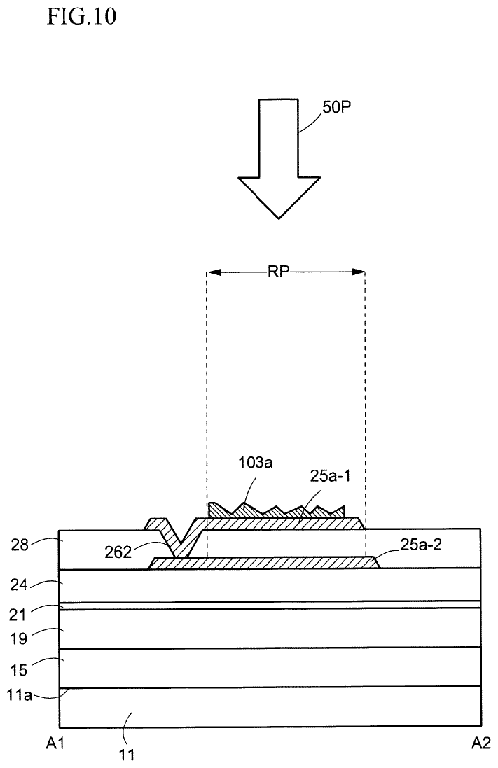

Next, in step S12 of FIG. 8, the first mounting pad 25a-1 to which the red LED chip 202R was connected is removed. For example, the first mounting pad 25a-1 to which the red LED chip 202R was connected is irradiated with a laser light 50P to remove the first mounting pad 25a-1 from the pixel 110. This process exposes the insulating layer 28 that was overlapped by the red LED chip 202R that was determined to be defective. As shown in FIG. 10, the first mounting pad 25a-1 to which the red LED chip 202R was connected is irradiated with the laser light 50P from the direction opposite to that of the insulating substrate 11. By irradiating the laser light 50P to the first mounting pad 25a-1, the energy of the laser light 50E is absorbed by the first mounting pad 25a-1 and the first mounting pad 25a-1 is sublimated and removed.

In step S12, although FIG. 10 shows an example of retaining part of the electrode between the red LED chip 202R and the first mounting pad 25a-1 without irradiating the laser light to the first mounting pad 25a-1 arranged in the contact hole 262, the laser light may be irradiated to the entire first mounting pad 25a-1 50P to remove the first mounting pad 25a-1 so as not to interfere with the newly mounted LED 402. In this case, the remaining part of the electrode can also be removed by irradiating the laser light 50P in step S12.

The laser light 50P may be selected as a laser light that is absorbed by the first mounting pad 25a-1. In the present embodiment, for example, infrared or visible light centered around the wavelength of 800 nm may be used as the laser light 50P. The laser light 50P may be an ultrashort pulsed laser such as a femtosecond laser. The laser light 50P may be a laser light with a different wavelength than the laser light 50E.

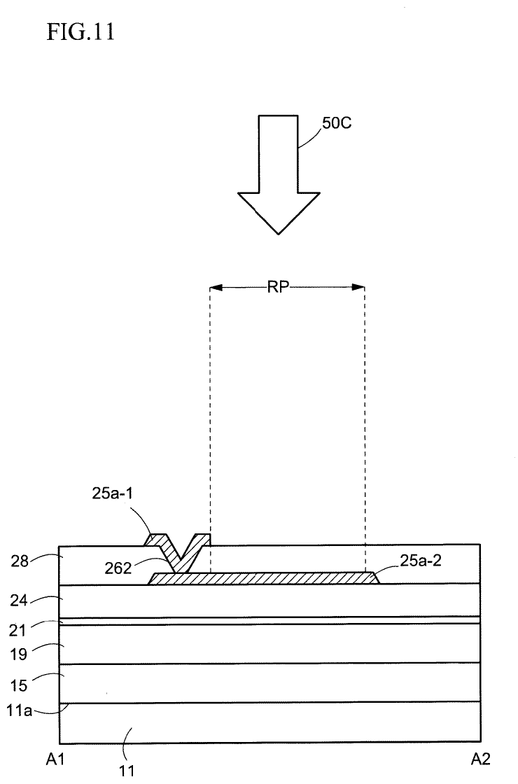

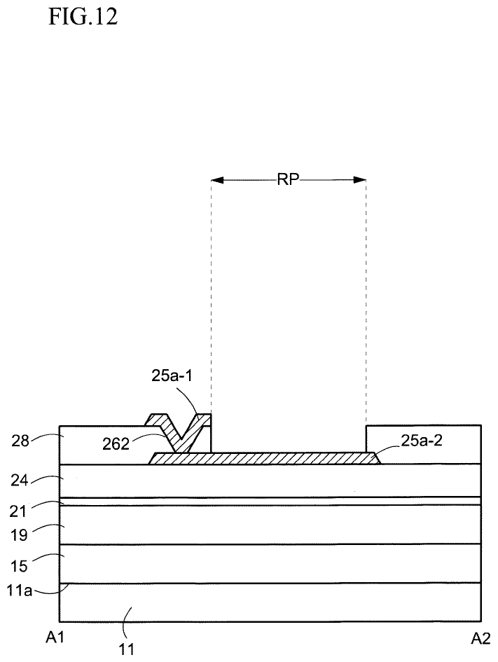

Further, in step S13 of FIG. 8, the insulating layer 28 that was overlapped by the first mounting pad 25a-1 that was removed in step For example, the insulating layer 28 that was S12 is removed. overlapped by the first mounting pad 25a-1 is irradiated with a laser light 50C, and the insulating layer 28 is removed. This process exposes the second mounting pad 25a-2 that was overlapped by the first mounting pad 25a-1, as shown in FIG. 12. As shown in FIG. 11, the insulating layer 28 that was overlapped by the first mounting pad 25a-1 is irradiated with the laser light 50P from the direction opposite to that of the insulating substrate 11. By irradiating the laser light 50C to the insulating layer 28, the energy of the laser light 50C is absorbed by the insulating layer 28 and the insulating layer 28 is removed.

The laser light 50C may be selected as the laser light that is absorbed by the insulating layer 28. In the present embodiment, for example, far-infrared light can be used as the laser light 50C. A gaseous laser such as a carbon dioxide (CO₂) laser can be used as the laser light 50C. The laser light 50C can be of a different wavelength than the laser light 50E and the laser light 50P.

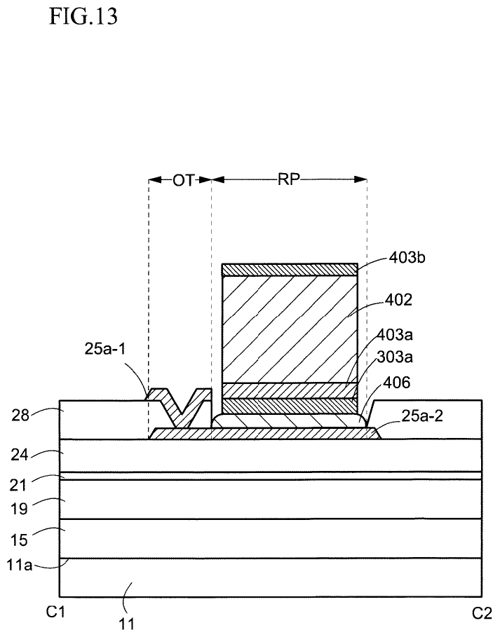

Finally, in step S14 of FIG. 8, a new LED chip 402 is mounted on the second mounting pad 25a-2 exposed by step S13. It is sufficient to use a well-known method of mounting LED chips to mount the new LED chip 402. For example, to mount the new LED chip 402, a conductive bonding layer 406 may be provided on the second mounting pad 25a-2 in advance, and the first connecting electrode 303a of the new LED chip 402 may be bonded to the conductive bonding layer 406. As shown in FIG. 13, the new LED chip 402 can be electrically connected to the second mounting pad 25a-2 through the conductive bonding layer 406, with the first connecting electrode 303a, terminal electrode 403a, and terminal electrode 403b provided in advance.

A conductive bonding material may be used as the conductive bonding layer 406. Conductive bonding materials such as solder, silver paste, anisotropic conductive film (ACF), etc., such as tin (Sn) or alloys containing tin may be used.

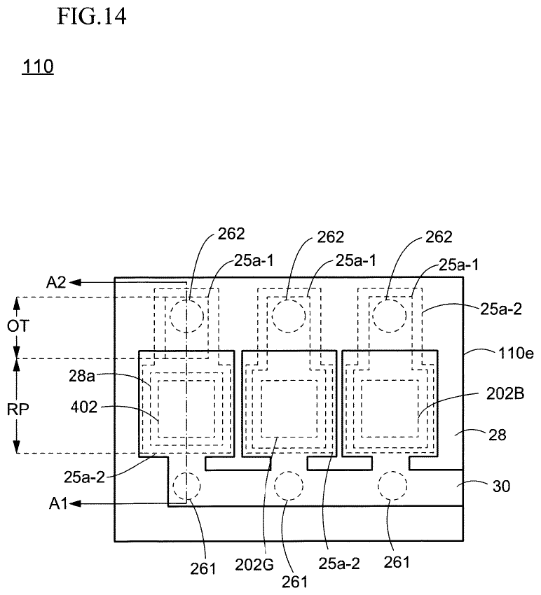

As described above, the new LED chip 402 can be mounted in the same pixel 110 in place of the red LED chip 202R that was determined to be defective on the circuit substrate 100. When a plurality of LED chips 202 are provided in the pixel 101 and one red LED chip 202R among them is determined to be defective and an LED chip 402 is mounted in place of that red LED chip 202R, as shown in FIG. 14, the one red LED chip 202R, the first mounting pad 25a-1 and the insulating layer 28 are removed in the repair region on the second mounting pad 25a-2, and the LED chip 402 is mounted on the second mounting pad 25a-2 in place of the one red LED chip 402. The region where the insulating layer 28 has been removed is shown as region 28a.

As described above, in a repair method for a display device according to the present embodiment, by removing the LED chip 202 determined to be defective, and the first mounting pad 25a-1 overlapping the LED chip 202 and the insulating layer 28, the second mounting pad 25a-2 overlapping the first mounting pad 25a-1 may be exposed, and a new LED chip 402 may be mounted on the second mounting pad 25a-2. In a plan view, the second mounting pad 25a-2 can be used as a spare mounting pad without providing an additional region for arranging the second mounting pad 25a-2 in the pixel 110, by mounting a new LED chip 402 on the second mounting pad 25a-2 that overlaps the first mounting pad 25a-1.

Each of the embodiments described above as an embodiment of the present invention can be appropriately combined and implemented as long as they do not contradict each other. The addition, deletion, or design change of components as appropriate, or the addition, deletion, or condition change of processes by those skilled in the art based on each embodiment are also included in the scope of the present invention as long as they are provided with the gist of the present invention.

Further, it is understood that, even if the advantageous effect is different from those provided by each of the above-described embodiments, the advantageous effect obvious from the description in the specification or easily predicted by the person skilled in the art is apparently derived from the present invention.

What is clamed is:

1. A display device comprising:
a first LED chip arranged in a pixel;
a first mounting pad arranged in the pixel and connected to the first LED chip;
a second mounting pad arranged in the pixel, overlapping the first mounting pad in a plan view and electrically connected to the second mounting pad, and
an insulating layer between the first mounting pad and the second mounting pad.

2. The display device according to claim 1, wherein
a thickness of the insulating layer is greater than or equal to 1 μm and less than or equal to 2 μm.

3. The display device according to claim 1, wherein
the first mounting pad comprises a first n-electrode side pad and a first p-electrode side pad corresponding to the first LED chip,
the second mounting pad comprises a second n-electrode side pad overlapping the first n-electrode side pad and a second p-electrode side pad overlapping the first p-electrode side pad in a plan view,
the first n-electrode side pad is electrically connected to the second n-electrode side pad, and
the first p-electrode side pad is electrically connected to the second p-electrode side pad.

4. The display device according to claim 1, wherein
the pixel comprises the first LED chip, the first mounting pad, the insulating layer, and a plurality of areas overlapped by the second mounting pad in a plan view,
a repair region is included where the first LED chip, the first mounting pad and the insulating layer were removed on the second mounting pad in at least one area in the plurality of areas, and
in the repair region, a second LED chip is electrically connected to the second mounting pad in place of the first LED chip.

5. A repair method for a display device, the method comprising:
irradiating a first laser light to a first LED chip determined to be defective in a pixel and removing the first LED chip;
irradiating a second laser light to a first mounting pad connected to the first LED chip in the pixel and removing the first mounting pad;
irradiating a third laser light to an insulating layer overlapping the first mounting pad, removing the insulating layer, and exposing a second mounting pad overlapping the first mounting pad in a plan view, and
mounting a second LED chip on the second mounting pad.

6. The repair method according to claim 5, further comprising:
wavelengths of the first laser light, the second laser light, and the third laser light are different.
